(19) United States
(12) Patent Application Publication
(10) Pub. No.: US 2024/0079359 A1
(43) Pub. Date: Mar. 7, 2024

(54) SEMICONDUCTOR PACKAGE

(71) Applicant: SAMSUNG ELECTRONICS CO., LTD., Suwon-si (KR)

(72) Inventor: Gayoung Kim, Suwon-si (KR)

(73) Assignee: SAMSUNG ELECTRONICS CO., LTD., Suwon-si (KR)

(21) Appl. No.: 18/202,126

(22) Filed: May 25, 2023

(30) Foreign Application Priority Data
Sep. 6, 2022 (KR) 10-2022-0112601

(51) Int. Cl. H01L 23/00

(52) U.S. Cl. CPC H01L 24/05; H01L 24/13; H01L 2224/0401; H01L 2224/05166; H01L 2224/05184; H01L 2224/05564; H01L 2224/05647; H01L 2224/05655; H01L 2224/13111; H01L 2224/13139; H01L 2224/13147

(57) ABSTRACT

A semiconductor package including a redistribution structure comprising a redistribution layer; a semiconductor chip electrically connected to the redistribution layer; bumps disposed on the redistribution structure; and under bump metallurgy (UBM) structures disposed between the bumps and the redistribution structure. Each of the UBM structures includes a first UBM layer including copper or a copper alloy; and a second UBM layer including nickel or nickel alloy and disposed between the redistribution structure and the first UBM layer. An area of a surface of the second UBM layer facing the first UBM layer is greater than an area of a surface of the first UBM layer facing the second UBM layer.

### CROSS-REFERENCE TO RELATED APPLICATION(S)

This application claims priority to Korean Patent Application No. 10-2022-0112601, filed on Sep. 6, 2022, in the Korean Intellectual Property Office, the disclosure of which is incorporated by reference herein in its entirety.

### BACKGROUND

The present disclosure relates to a semiconductor package.

In general, a semiconductor chip may be implemented as a semiconductor package such as a wafer level package (WLP) or a panel level package (PLP), and the semiconductor package may be used as an electronic component of a device.

A semiconductor package may include a redistribution layer for electrically connecting a semiconductor chip to a device. The redistribution layer may have a structure in which redistributions finer than wirings of a wiring layer of a general printed circuit board are extended horizontally.

The redistribution layer may be electrically connected to the bumps to vertically extend the electrical connection path, and under bump metallurgy (UBM) may improve electrical connection efficiency between the redistribution layer and the bumps.

### SUMMARY

One or more example embodiments provide a semiconductor package in which reliability of UBM structures is improved.

According to an aspect of an example embodiment, a semiconductor package includes: a redistribution structure comprising a redistribution layer; a semiconductor chip electrically connected to the redistribution layer; bumps disposed on the redistribution structure; and under bump metallurgy (UBM) structures disposed between the bumps and the redistribution structure, wherein each of the UBM structures comprises: a first UBM layer comprising copper or a copper alloy; and a second UBM layer comprising nickel or nickel alloy and disposed between the redistribution structure and the first UBM layer, wherein an area of a surface of the second UBM layer facing the first UBM layer, is greater than an area of a surface of the first UBM layer facing the second UBM layer.

According to an aspect of an example embodiment, a semiconductor package includes: a redistribution structure comprising a redistribution layer; a semiconductor chip electrically connected to the redistribution layer; bumps disposed on the redistribution structure; and UBM structures disposed between the bumps and the redistribution structure, wherein each of the UBM structures comprises: a first UBM layer comprising a first metal material or an alloy of the first metal material; and a second UBM layer containing a second metal material different from the first metal material or an alloy of the second metal material and disposed between the redistribution structure and the first UBM layer, and wherein a side surface of the first UBM layer comprises a shape that is more curved than a shape of a side surface of the second UBM layer.

According to an aspect of an example embodiment, a semiconductor package includes: a redistribution structure comprising a redistribution layer; a semiconductor chip electrically connected to the redistribution layer; bumps arranged on the redistribution structure; and UBM structures disposed between the bumps and the redistribution structure, wherein each of the UBM structures comprises: a first UBM layer comprising a first metal material or an alloy of the first metal material; a second UBM layer comprising a second metal material different from the first metal material or an alloy of the second metal material and disposed between the redistribution structure and the first UBM layer; a first intermetallic compound structure, comprising an intermetallic compound in which at least a portion of a material of the bumps and the first metal material are bonded, and connected between the bumps and the first UBM layer; and a second intermetallic compound structure, comprising an intermetallic compound in which at least a portion of the material of the bumps and the second metal material are bonded, and connected between the bumps and the second UBM layer to surround and seal at least a portion of the first UBM layer.

### BRIEF DESCRIPTION OF DRAWINGS

The above and other aspects and features will be more apparent from the following description of example embodiments, taken in conjunction with the accompanying drawings, in which:

FIG. 1A is an enlarged cross-sectional view of a semiconductor package according to an example embodiment;

FIG. 1B is an enlarged plan view of a semiconductor package according to an example embodiment;

FIG. 1C is a cross-sectional view illustrating a semiconductor package according to an example embodiment;

FIGS. 2A and 2B are cross-sectional views illustrating a redistribution structure of a semiconductor package and various structures of a semiconductor chip according to an example embodiment;

FIGS. 3A and 3B are cross-sectional views illustrating various structures of UBM structures of a semiconductor package according to an example embodiment; and

FIGS. 4A to 4F are cross-sectional views illustrating a method of manufacturing a semiconductor package according to an example embodiment.

### DETAILED DESCRIPTION

Example embodiments will be described more fully with reference to the accompanying drawings, in which example embodiments are shown. Embodiments described herein are provided as examples, and thus, the present disclosure is not limited thereto, and may be realized in various other forms. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. Specific shapes, structures, and characteristics described herein with respect to one embodiment may be implemented in another embodiment. Additionally, it should be understood that the location or arrangement of individual components within each disclosed embodiment may be changed. Like reference numbers in the drawings indicate the same or similar function throughout the various aspects.

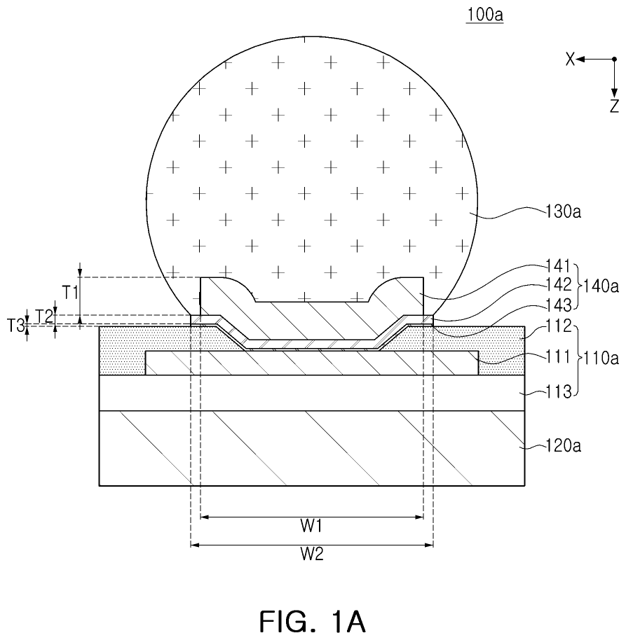

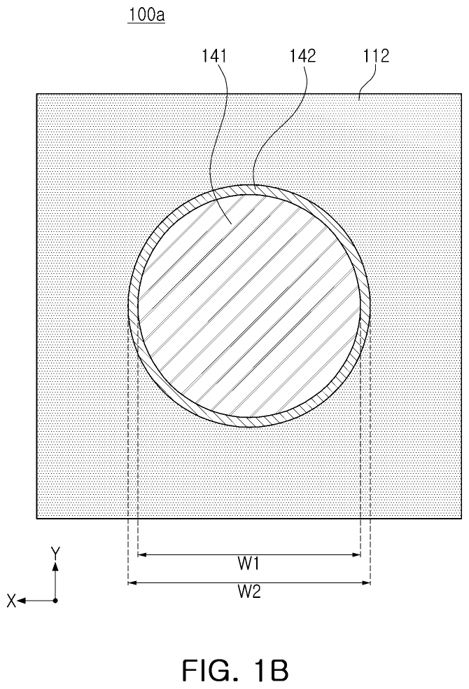

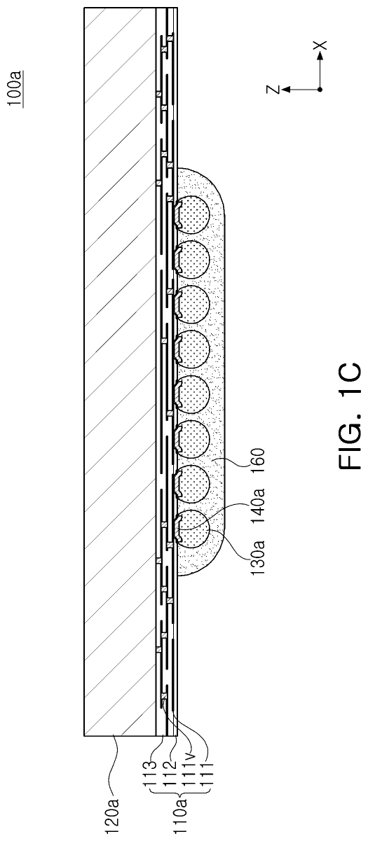

FIG. 1A is an enlarged cross-sectional view of a semiconductor package according to an example embodiment, FIG. 1B is an enlarged plan view of a semiconductor package according to an example embodiment, and FIG. 1C is a cross-sectional view illustrating a semiconductor package according to an example embodiment.

Referring to FIGS. 1A, 1B, and 1C, a semiconductor package 100a according to an example embodiment may include a redistribution structure 110a, a semiconductor chip 120a, bumps 130a, and under bump metallurgy (UBM) structures 140a, and each of the UBM structures 140a may include a first UBM layer 141 and a second UBM layer 142.

The redistribution structure 110a may include a redistribution layer 111.

The semiconductor chip 120a may be electrically connected to the redistribution layer 111. The semiconductor chip 120a may be disposed on the redistribution structure 110a. For example, the semiconductor chip 120a may include a body portion including a semiconductor material such as silicon (Si), germanium (Ge), or gallium arsenide (GaAs), and an element layer or an active layer disposed below the body portion and including an integrated circuit (IC). The semiconductor chip 120a may include a logic semiconductor chip and/or a memory semiconductor chip. The logic semiconductor chip may be a microprocessor, for example, a central processing unit (CPU), a graphic processing unit (GPU), a field programmable gate array (FPGA), an application processor (AP), a digital signal processor, a cryptographic processor, a controller, or an application specific integrated circuit (ASIC). The memory semiconductor chip may be a volatile memory such as a dynamic random access memory (DRAM) or a static random access memory (SRAM), or a non-volatile memory such as flash memory.

The bumps 130a may be arranged on the redistribution structure 110a. For example, the bumps 130a may have a ball shape or a column shape, and may include solder including tin (Sn) or an alloy (Sn—Ag—Cu) containing tin (Sn). The bumps 130a may have a relatively low melting point compared to other metal materials, and may thus be connected and fixed to the UBM structures 140a by, for example, a thermal compression bonding (TCB) process or a reflow process.

The UBM structures 140a may be arranged between the bumps 130a and the redistribution structure 110a.

The first UBM layer 141 may include copper or a copper alloy. Since copper or a copper alloy may have high first conductivity and high first wettability with respect to the bumps 130a, the first UBM layer 141 may increase electrical connection efficiency between the bumps 130a and the redistribution layer 111.

The second UBM layer 142 may include nickel or a nickel alloy and may be disposed between the redistribution structure 110a and the first UBM layer 141. Nickel or a nickel alloy may have high second conductivity and high second wettability to the bumps 130a.

Accordingly, the UBM structures 140a including the first and second UBM layers 141 and 142 may have relatively high conductivity and high wettability with respect to the bumps 130a. Although the second conductivity may be slightly lower than the first conductivity, and the second wettability may be slightly lower than the first wettability, the corrosion resistance of nickel or a nickel alloy to the external environment (e.g., air, impurities) may be higher than corrosion resistance of copper or a copper alloy.

Therefore, when the second UBM layer 142 is disposed in a portion of the UBM structures 140a with a relatively higher possibility of being exposed to the external environment, since the possibility of the first UBM layer 141 being exposed to the external environment may be relatively lowered, the corrosion resistance of the UBM structures 140a may be improved.

Since a diameter W2 of the upper surface of the second UBM layer 142 may be longer than a diameter W1 of the lower surface of the first UBM layer 141, the area of the surface of the second UBM layer 142, facing the first UBM layer 141, may be larger than the area of the surface of the first UBM layer 141, facing the second UBM layer 142. The areas and diameters W1 and W2 may be measured by analysis using at least one of a micrometer, a transmission electron microscope (TEM), an atomic force microscope (AFM), a scanning electron microscope (SEM), a focused ion beam (FIB) optical microscope, and a surface profiler.

Respective parts within the UBM structures 140a may be more easily exposed to the external environment as the distance from the center of the UBM structures 140a increases. Therefore, the possibility of exposure of the edge portion of the second UBM layer 142 having a larger horizontal size, to the external environment, may be relatively high, and the possibility of exposure of the first UBM layer 141 having a smaller horizontal size, to the external environment, may decrease.

Therefore, the possibility of corrosion of the first UBM layer 141 containing copper or a copper alloy may be structurally suppressed, and even in the case in which a portion of the surface of the second UBM layer 142 containing nickel or a nickel alloy is exposed to air, the material may not corrode well, and thus, the overall corrosion resistance of the UBM structures 140a may be increased. In general, since the reliability of a structure formed of a metal material may deteriorate due to corrosion, the UBM structures 140a having improved corrosion resistance may have relatively higher reliability. The reliability may include Board Level Reliability (BLR).

For example, referring to FIG. 1B, a region that does not overlap with the first UBM layer 141 on the surface of the second UBM layer 142 facing the first UBM layer 141 may enclose or completely enclose the region overlapping with the first UBM layer 141. Accordingly, since the first UBM layer 141 may be sealed by the second UBM layer 142 and the bumps 130a, the possibility of corrosion of the first UBM layer 141 may be prevented.

In an example embodiment, the second UBM layer 142 containing nickel or a nickel alloy may include a little more impurity such as phosphorus (P) according to a forming process (e.g., electroless plating), and may have the potential to form a structure in which phosphorus (P) is layered on the surface of the second UBM layer 142, according to the reaction between the material of the bumps 130a and nickel. However, since the copper of the first UBM layer 141 may react to the material (e.g., tin) of the bumps 130a preferentially than the nickel of the second UBM layer 142, the thickness of the structure in which the phosphorus (P) forms a layer may be reduced. In an example embodiment, the thinner the thickness of the phosphorus (P)-layered structure, the higher the reliability of the UBM structures 140a.

For example, each of the UBM structures 140a may further include a seed metal layer 143 containing a seed material (e.g. Ti, TiW) different from copper or a copper alloy and different from nickel or a nickel alloy and disposed between the redistribution structure 110a and the second UBM layer 142 to contact the second UBM layer 142.

The seed metal layer 143 may act as a seed for the formation process (e.g., electroless plating) of the second UBM layer 142, and may thus have the same horizontal size as the horizontal size of the second UBM layer 142. Accordingly, the area of the surface of the seed metal layer 143 facing the second UBM layer 142 may be larger than the area of the surface of the first UBM layer 141 facing the second UBM layer 142.

For example, a thickness T1 of the first UBM layer 141 may be greater than a thickness T2 of the second UBM layer 142, and the thickness T2 of the second UBM layer 142 may be greater than a thickness T3 of the seed metal layer 143. Accordingly, the overall weight of the metal material of the UBM structures 140a may have a characteristic that a metal material having higher conductivity and wettability occupies a higher weight, so that the UBM structures 140a may efficiently improve conductivity and wettability. In addition, the thickness of a structure in which phosphorus (P) that is likely to be formed on the surface of the second UBM layer 142 is formed as a layer may also be reduced.

For example, the total thickness of the first and second UBM layers 141 and 142 may be greater than or equal to 1 μm and less than or equal to 50 μm. When the total thickness of the first and second UBM layers 141 and 142 is 50 μm or less, an overall degree of integration of the semiconductor package 100a may be increased. When the total thickness of the first and second UBM layers 141 and 142 is 1 μm or more, a structure in which the first UBM layer 141 is not exposed according to the horizontal size difference between the first and second UBM layers 141 and 142 may be stably implemented.

The thickness may be measured, for example, by using at least one of a micrometer, TEM, AFM, SEM, FIB, an optical microscope, and a surface profiler, and may be calculated as an average value of thickness measurements at a plurality of points.

For example, referring to FIGS. 1A, 1B and 1C, the redistribution structure 110a may further include at least one of the first insulating layer 112 and the second insulating layer 113 as well as the redistribution layer 111.

The first and second insulating layers 112 and 113 include an insulating material, and may include, for example, a thermosetting resin such as epoxy resin or a thermoplastic resin such as polyimide. For example, the first and second insulating layers 112 and 113 may include a photosensitive insulating material such as Photo Imageable Dielectric (PID) resin. Alternatively or additionally, the first and second insulating layers 112 and 113 may include a resin mixed with an inorganic filler, for example, Ajinomoto Build-up Film (ABF). Alternatively or additionally, the first and second insulating layers 112 and 113 may include prepreg, flame retardant (FR-4), or bismaleimide triazine (BT). The first and second insulating layers 112 and 113 may include the same or different materials, and a boundary therebetween may or may not be distinguished depending on materials and processes constituting respective layers.

The first insulating layer 112 may surround portions of the respective UBM structures 140a. A portion of the first insulating layer 140a may be positioned between another portion of each of the UBM structures 140a and a portion of the redistribution layer 111. Accordingly, the UBM structures 140a may be formed after the first insulating layer 112 is formed, and may have a horizontal size greater than the horizontal size of the opening of the first insulating layer 112.

The second insulating layer 113 may be disposed between the redistribution layer 111 and the semiconductor chip 120a. There may be one or a plurality of each of the second insulating layer 113 and the redistribution layer 111, and the second insulating layers 113 and the redistribution layers 111 may be alternately stacked.

The redistribution layers 111 and redistribution vias 111v may form an electrical path. The redistribution layers 111 may be disposed in a line shape on the X-Y plane, and the redistribution vias 111v may have a cylindrical shape with side surfaces that are inclined toward the bottom or the top so as to narrow at the bottom or the top. The redistribution vias 111v are illustrated as a filled via structure in which the inside is completely filled with a conductive material, but example embodiments are not limited thereto. For example, the redistribution vias 111v may have a conformal via shape in which a metal material is formed along an inner wall of the via hole.

The redistribution layers 111 and the redistribution vias 111v may include a conductive material, for example, copper (Cu), aluminum (Al), silver (Ag), tin (Sn), gold (Au), nickel (Ni), lead (Pb), titanium (Ti), or alloys thereof.

A portion of the uppermost redistribution layer 111 of the redistribution layers, which does not vertically overlap the first insulating layer 112, may be a pad. For example, the pad may have the same shape as the circular shape of the first and second UBM layers 141 and 142 illustrated in FIG. 1B, and may have a horizontal size similar to a horizontal size of the first and second UBM layers 141 and 142.

For example, referring to FIG. 1C, the semiconductor package 100a may further include a non-conductive film layer 160. The non-conductive film layer 160 may be disposed to surround the bumps 130a, on the lower surface of the redistribution structure 110a. The non-conductive film layer 160 may be referred to as an underfill layer, may include a non-conductive polymer, and may include a non-conductive paste (NCP).

The semiconductor package 100a of FIG. 1C has a fan-in structure in which the redistribution structure 110a and the semiconductor chip 120a completely overlap each other vertically, but the semiconductor package 100a according to example embodiments is not limited to a fan-in structure.

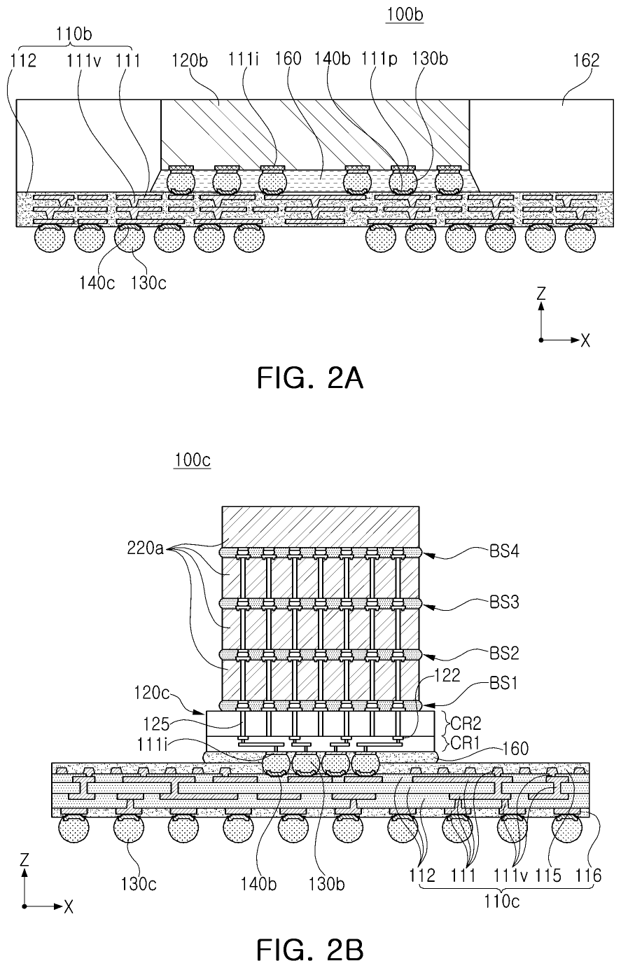

FIGS. 2A and 2B are cross-sectional views illustrating various structures of a redistribution structure and a semiconductor chip of a semiconductor package according to an example embodiment.

Referring to FIG. 2A, a semiconductor package 100b according to an example embodiment may have a fan-out structure in which a portion of a redistribution structure 110b vertically overlaps a semiconductor chip 120b and the rest of the redistribution structure 110b does not vertically overlap the semiconductor chip 120b. The fan-out structure may be extended to a Package on Package (POP) structure or may be a System in Package (SIP) structure.

The semiconductor chip 120b may be mounted on the upper surface of the redistribution structure 110b by flip-chip bonding, and may include connection pads 111i disposed on the lower surface of the semiconductor chip 120b. For example, the connection pads 111i may include a conductive material such as tungsten (W), aluminum (Al), or copper (Cu), and may be a pad of a bare chip, for example, an aluminum (Al) pad, but may be a pad of a packaged chip, for example, a copper (Cu) pad, according to example embodiments.

Accordingly, bumps 130b may be connected between the semiconductor chip 120b and the redistribution structure 110b. The UBM structures 140b may be arranged between the bumps 130b and additional pad 111p of the redistribution structure 110b, and may have the same or a substantially similar structure as the UBM structures of FIG. 1A.

In addition, bumps 130c may be arranged on the lower surface of the redistribution structure 110b and may be configured to be connected to a printed circuit board of a device or an additional redistribution structure. The UBM structures 140c may be arranged between the bumps 130c and the redistribution structure 110b and may have the same structure as the UBM structures of FIG. 1A.

Referring to FIG. 2A, the semiconductor package 100b according to an example embodiment may further include an encapsulant 162. The encapsulant 162 may seal and protect the semiconductor chip 120b. The encapsulant 162 may be disposed to cover the side surfaces and the upper surface of the semiconductor chip 120b, but example embodiments are not limited thereto. The encapsulant 162 may include an insulating material, for example, a thermosetting resin such as epoxy resin, a thermoplastic resin such as polyimide, ABF, FR-4, BT, Epoxy Molding Compound (EMC), prepreg including inorganic filler and/or glass fiber, or PID.

Referring to FIG. 2B, a semiconductor chip 120c of a semiconductor package 100c according to an example embodiment may be disposed between semiconductor chips 220a and a redistribution structure 110c, and the bumps 130b may be connected between the semiconductor chip 120c and the redistribution structure 110b. The UBM structures 140b may be arranged between the bumps 130b and the redistribution structure 110b.

For example, the combined structure of the semiconductor chip 120c and the semiconductor chips 220a may be a 3D integrated circuit structure as a SIP, the semiconductor chip 120c is a logic semiconductor chip, and the semiconductor chips 220a may be memory semiconductor chips.

For example, the semiconductor chip 120c may have a lower first region CR1 and an upper second region CR2, and may further include device layers 122 and through vias 125. The first region CR1 may be a device region, and may be a region in which elements such as transistors and/or memory cells constituting a semiconductor chip are formed based on the second region CR2. The second region CR2 may be a substrate region, and may include, for example, a semiconductor material such as silicon (Si).

The device layers 122 may be disposed in the first region CR1 to configure the elements. The through-vias 125 may pass through the second region CR2 of the semiconductor chip 120c. In some example embodiments, the through-vias 125 may further penetrate at least a portion of the first region CR1. The through-vias 125 may be electrically connected to the device layers 122 of the first region CR1 and may provide an electrical connection between the semiconductor chips 220a and the redistribution structure 110c. The through-vias 125 may be formed of a conductive material, and may include, for example, at least one of tungsten (W), aluminum (Al), and copper (Cu). The redistribution structure 110c may have the same or a substantially similar structure as the redistribution structure of FIG. 1A.

The semiconductor chips 220a may be stacked and disposed in the Z direction on the semiconductor chip 120c. The semiconductor chips 220a may include through-vias 125 except for uppermost semiconductor chips. A first connection region BS1 may be located between the semiconductor chip 120c and the semiconductor chips 220a, and second to fourth connection regions BS2, BS3, and BS4 may be located between the semiconductor chips 220a, respectively. Although not specifically illustrated, at least a portion of the first to fourth connection regions BS1, BS2, BS3, and BS4 may have substantially the same or similar structure as a connection region between the redistribution structure 110c and the semiconductor chip 120c. For example, each of the first to fourth connection regions BS1, BS2, BS3, and BS4 may include bumps arranged horizontally, may include pads disposed above and below the bumps, and may include a non-conductive film layer surrounding the bumps.

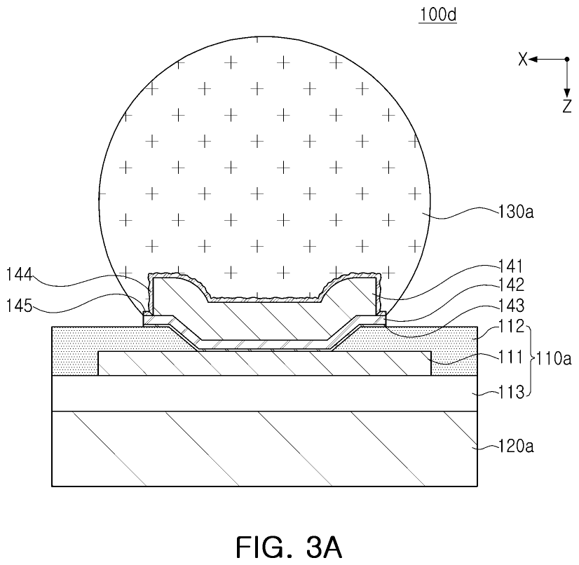

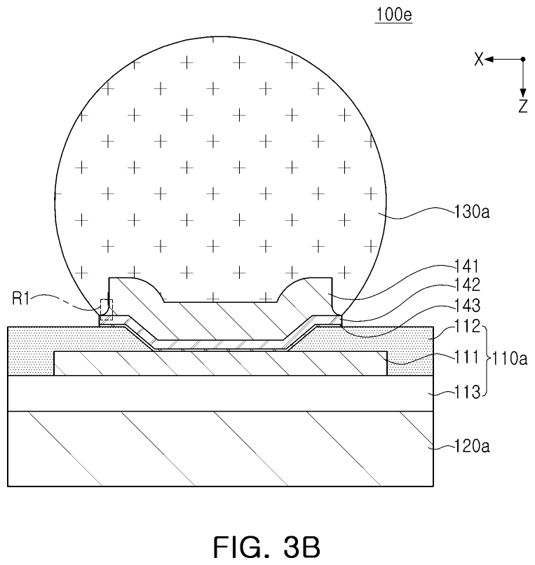

FIGS. 3A and 3B are cross-sectional views illustrating various structures of UBM structures of a semiconductor package according to an example embodiment.

Referring to FIG. 3A, the UBM structures of a semiconductor package 100d according to an example embodiment may include a first UBM layer 141, a second UBM layer 142, a first intermetallic compound structure 144, and a second intermetallic compound structure 145.

The first UBM layer 141 may include a first metal material or an alloy of the first metal material. The first metal material may be copper, but example embodiments are not limited thereto.

The second UBM layer 142 may include a second metal material different from the first metal material, or an alloy of the second metal material, and may be disposed between the redistribution structure 110a and the first UBM layer 141. The first metal material may be nickel, but example embodiments are not limited thereto.

The first intermetallic compound structure 144 may include an intermetallic compound in which at least a portion (e.g., tin) of the material of the bumps 130a and the first metal material (e.g., copper) are combined, and may be connected between the bumps 130a and the first UBM layer 141.

The second intermetallic compound structure 145 may include an intermetallic compound in which at least a portion (e.g., tin) of the material of the bumps 130a and the second metal material (e.g., nickel) are combined, and may be connected between the bumps 130a and the second UBM layer 142.

For example, the first and second intermetallic compound structures 144 and 145 may be formed by a thermal compression bonding (TCB) process or a reflow process in a state in which the bumps 130a contact the first and second UBM layers 141 and 142.

For example, since the reactivity of copper to tin may be higher than the reactivity of nickel to tin, a portion of the nickel included in the second UBM layer 142 may be used to form the first intermetallic compound structure 144, and the other part may be used to form the second intermetallic compound structure 145. Accordingly, the second intermetallic compound structure 145 may be thinner than the first intermetallic compound structure 144.

The second intermetallic compound structure 145 may be formed on a region of the upper surface of the second UBM layer 142, which does not contact the first UBM layer 141, and the non-contact region may surround a region of the upper surface of the second UBM layer 142, which is in contact with the first UBM layer 141. Therefore, the second intermetallic compound structure 145 of an example embodiment may surround at least a portion of the first UBM layer 141.

The second intermetallic compound structure 145 may densely fill the minute gaps between the second UBM layer 142 and the bumps 130a to densely connect the second UBM layer 142 and the bumps 130a. Therefore, the first UBM layer 141 may be sealed by the second intermetallic compound structure 145. Accordingly, in an example embodiment, the possibility that the first UBM layer 141 is exposed to an external environment (e.g., air or impurities) may be more effectively suppressed.

Referring to FIG. 3B, a side surface R1 of the first UBM layer 141 of the UBM structure of a semiconductor package 100e according to an example embodiment may be curved. For example, the side surface R1 of the first UBM layer 141 of the UBM structure of a semiconductor package 100e may include a shape that is more curved than a shape of the side surface of the second UBM layer 142. The side surface R1 of the first UBM layer 141 of the UBM structure of a semiconductor package 100e may have a concave shape in an area adjacent to the second UBM layer 142. In an example embodiment, a side surface of the second UBM layer 142 may be substantially vertical and substantially flat. In an example embodiment, a side surface R1 of the first UBM layer 141 of the UBM structure of a semiconductor package 100e may be in the form of a more curved tail or a more gentle taper than a shape of the side surface of the second UBM layer 142. The fact that the side surface is more curved may mean that the area or volume of the area virtually formed by the combination of the side surface and a virtual straight line extending from the edge of the upper surface to the edge of the lower surface is relatively larger, and that the side surface is more gentle may mean that the angle formed by the lower surface and the side surface is relatively smaller.

For example, a more curved tail shape or a more gentle tapered shape of the side surface R1 of the first UBM layer 141 may be formed by wet etching on the edge portion of the first UBM layer 141. Since the edge portion of the second UBM layer 142 may hardly be etched, the side surface of the second UBM layer 142 may have a shape that is relatively closer to a straight line or a shape in which an angle formed with the lower surface of the second UBM layer 142 is close to vertical.

For example, when the first and second UBM layers 141 and 142 include copper and nickel, respectively, an etching solution used for wet etching may be an etching solution that almost reacts only to copper among copper and nickel. Accordingly, the horizontal size difference between the first and second UBM layers 141 and 142 may be implemented more efficiently.

In example embodiments with a more curved tail shape or a more gentle tapered shape of the side surface R1 of the first UBM layer 141, the bumps 130a may slide more fluidly toward the second UBM layer 142 on the surface when the bumps 130a are formed on the surfaces of the first and second UBM layers 141 and 142 by a TCB process or a reflow process.

Accordingly, since the bumps 130a may surround the first UBM layer 141 more deeply in three dimensions, the possibility that the first UBM layer 141 is exposed to an external environment (e.g., air or impurities) may be suppressed more effectively.

The degree of curvature of the curvilinear tail shape of the side surface R1 of the first UBM layer 141 may be measured according to how continuously the slope of each z-coordinate of the side surface R1 changes, and the degree of gentleness of the gentle tapered shape of the side surface R1 of the first UBM layer 141 may be measured according to how low the average value of the slope of each z-coordinate of the side surface R1 is. The slope may be measured by analysis using at least one of a micrometer, a TEM, an AFM, a SEM, a FIB, an optical microscope, and a surface profiler.

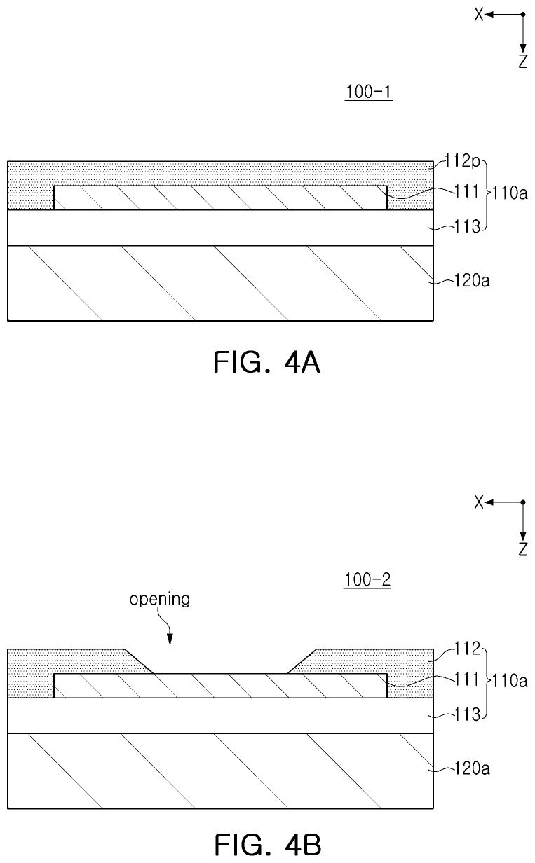

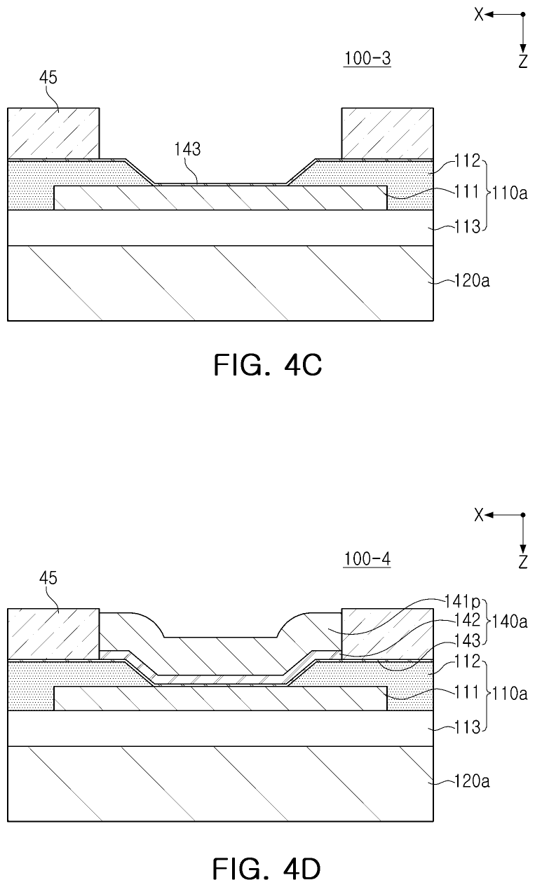

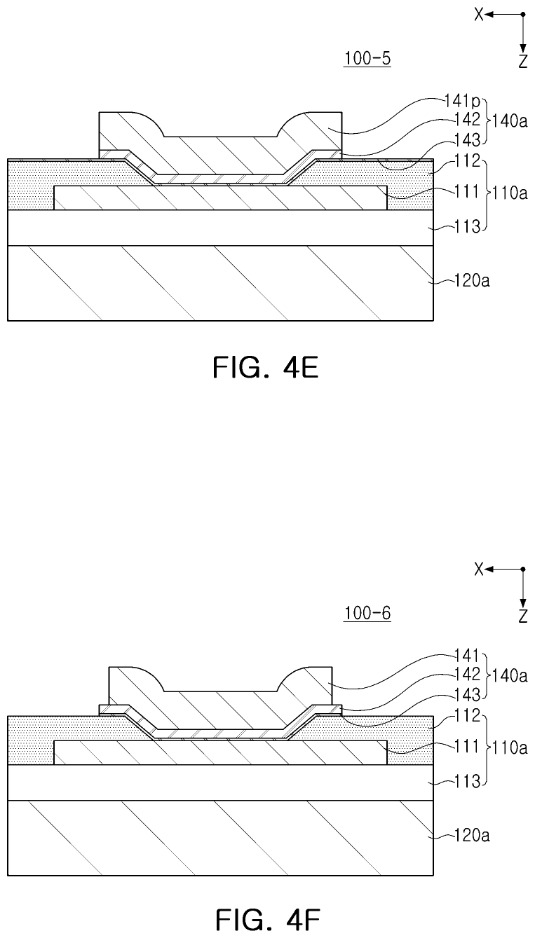

FIGS. 4A to 4F are cross-sectional views illustrating a method of manufacturing a semiconductor package according to an example embodiment.

Referring to FIGS. 4A to 4C, a method of manufacturing a semiconductor package according to an example embodiment may include forming a redistribution structure 110a on the semiconductor chip 120a (100-1), forming an opening in a first insulating layer 112p of the redistribution structure 110a (100-2), and forming a protective pattern 45 on the first insulating layer 112 (100-3).

Referring to FIGS. 4C and 4D, the method of manufacturing a semiconductor package according to an example embodiment may include forming a seed metal layer 143 on the redistribution structure 110a including the redistribution layer 111, forming a second UBM layer 142 containing nickel or an alloy of nickel on the seed metal layer 143, and forming a first UBM layer 141p containing copper or an alloy of copper on the second UBM layer 142 (100-4).

For example, the seed metal layer 143 may be formed by a sputtering process, and the first and second UBM layers 141p and 142 may be formed by an electroless plating process. Accordingly, the seed metal layer 143 may be formed earlier than the protective pattern 45, and may thus be disposed between the protective pattern 45 and the first insulating layer 112. In example embodiments, the seed metal layer 143 may be formed on the upper surface of the protective pattern 45 instead of the lower surface.

Referring to FIG. 4E, the method of manufacturing a semiconductor package according to an example embodiment may include removing the protective pattern 45 (100-5). For example, the protective pattern 45 may contain a material that may be used in an exposure and development manner, such as PID.

Referring to FIG. 4F, the method of manufacturing a semiconductor package according to an example embodiment may include etching the edge portion of the first UBM layer 141p using etching means (e.g., wet etching) that etch copper faster than nickel (100-6), in a state in which at least a portion of the first UBM layer 141p and at least a portion of the second UBM layer 142 are exposed. Accordingly, the area of the lower surface of the first UBM layer 141 may be smaller than the area of the upper surface of the second UBM layer 142, and a portion of the seed metal layer 143, which does not vertically overlap the second UBM layer 142, may also be etched.

In example embodiments, the additional protective pattern may be formed on the upper surface of the first UBM layer 141p and may be removed after the first UBM layer 141 is formed. Since the etching time of the operation 100-6 of etching the edge portion of the first UBM layer 141p may match the time for etching the thin seed metal layer 143, the first UBM layer 141 may be formed without an additional protective pattern.

Referring to FIGS. 4F and 1A, the method of manufacturing a semiconductor package according to an example embodiment may include forming the bumps 130a on the first UBM layer 141 of which an edge portion is etched. The bump 130a may be ultimately formed by a TCB process or a reflow process. The semiconductor package 100a of FIG. 1A is not construed as being limited by the method of manufacturing a semiconductor package in FIGS. 4A to 4F.

As set forth above, according to example embodiments, reliability (or reliability compared to a unit price/size) of UBM structures may be improved.

While aspects of example embodiments have been particularly shown and described, it will be understood that various changes in form and details may be made therein without departing from the spirit and scope of the following claims.

What is claimed is:

1. A semiconductor package comprising:
a redistribution structure comprising a redistribution layer;
a semiconductor chip electrically connected to the redistribution layer;
bumps disposed on the redistribution structure; and
under bump metallurgy (UBM) structures disposed between the bumps and the redistribution structure,
wherein each of the UBM structures comprises:
a first UBM layer comprising copper or a copper alloy; and
a second UBM layer comprising nickel or nickel alloy and disposed between the redistribution structure and the first UBM layer,
wherein an area of a surface of the second UBM layer facing the first UBM layer, is greater than an area of a surface of the first UBM layer facing the second UBM layer.

2. The semiconductor package of claim 1, wherein each of the UBM structures further comprises a seed metal layer comprising a seed material different from copper and different from nickel, disposed between the redistribution structure and the second UBM layer, and contacting the second UBM layer,
wherein an area of a surface of the seed metal layer facing the second UBM layer, is greater than the area of the surface of the first UBM layer facing the second UBM layer.

3. The semiconductor package of claim 1, wherein on the surface of the second UBM layer facing the first UBM layer, a region not overlapping the first UBM layer surrounds a region overlapping the first UBM layer.

4. The semiconductor package of claim 1, wherein the redistribution structure further comprises a first insulating layer surrounding a first portion of each of the UBM structures,
wherein a portion of the first insulating layer is disposed between a second portion of each of the UBM structures and a portion of the redistribution layer.

5. The semiconductor package of claim 4, wherein the redistribution structure further comprises a second insulating layer disposed between the redistribution layer and the semiconductor chip.

6. The semiconductor package of claim 1, wherein the semiconductor chip is disposed on the redistribution structure.

7. The semiconductor package of claim 1, wherein a thickness of the first UBM layer is greater than a thickness of the second UBM layer.

8. The semiconductor package of claim 7, wherein a total thickness of the first UBM layer and the second UBM layer is 1 μm or more and 50 μm or less.

9. The semiconductor package of claim 1, wherein a portion of the surface of the second UBM layer is exposed to air.

10. The semiconductor package of claim 1, wherein each of the UBM structures further comprises:
a first intermetallic compound structure, comprising an intermetallic compound in which copper is bonded to at least a portion of a material of the bumps, and connected between the bumps and the first UBM layer; and
a second intermetallic compound structure, comprising an intermetallic compound in which at least a portion of the material of the bumps and nickel are bonded, and connected between the bumps and the second UBM layer to enclose and seal at least a portion of the first UBM layer.

11. The semiconductor package of claim 1, wherein a side surface of the first UBM layer comprises a shape that is more curved than a shape of a side surface of the second UBM layer.

12. A semiconductor package comprising:
a redistribution structure comprising a redistribution layer;
a semiconductor chip electrically connected to the redistribution layer;
bumps disposed on the redistribution structure; and
under bump metallurgy (UBM) structures disposed between the bumps and the redistribution structure,
wherein each of the UBM structures comprises:
a first UBM layer comprising a first metal material or an alloy of the first metal material; and
a second UBM layer containing a second metal material different from the first metal material or an alloy of the second metal material and disposed between the redistribution structure and the first UBM layer, and
wherein a side surface of the first UBM layer comprises a shape that is more curved than a shape of a side surface of the second UBM layer.

13. The semiconductor package of claim 12, wherein an area of a surface of the second UBM layer facing the first UBM layer, is greater than an area of a surface of the first UBM layer facing the second UBM layer.

14. The semiconductor package of claim 13, wherein each of the UBM structures further comprises:
a seed metal layer comprising a seed material different from copper and different from nickel, disposed between the redistribution structure and the second UBM layer, and contacting the second UBM layer,
wherein an area of a surface of the seed metal layer facing the second UBM layer, is greater than an area of a surface of the first UBM layer facing the second UBM layer.

15. The semiconductor package of claim 14, wherein the first metal material comprises copper, and
the second metal material comprises nickel.

16. The semiconductor package of claim 15, wherein a thickness of the first UBM layer is greater than a thickness of the second UBM layer, and
a total thickness of the first UBM layer and the second UBM layer is 1 μm or more and 50 μm or less.

17. The semiconductor package of claim 16, wherein each of the UBM structures further comprises:
a first intermetallic compound structure, comprising an intermetallic compound in which copper is bonded to at least a portion of a material of the bumps, and connected between the bumps and the first UBM layer; and
a second intermetallic compound structure, comprising an intermetallic compound in which at least a portion of the material of the bumps and nickel are bonded, and connected between the bumps and the second UBM layer to enclose and seal at least a portion of the first UBM layer.

18. A semiconductor package comprising:
a redistribution structure comprising a redistribution layer;
a semiconductor chip electrically connected to the redistribution layer;
bumps arranged on the redistribution structure; and
under bump metallurgy (UBM) structures disposed between the bumps and the redistribution structure,
wherein each of the UBM structures comprises:
a first UBM layer comprising a first metal material or an alloy of the first metal material;
a second UBM layer comprising a second metal material different from the first metal material or an alloy of the second metal material and disposed between the redistribution structure and the first UBM layer;
a first intermetallic compound structure, comprising an intermetallic compound in which at least a portion of a material of the bumps and the first metal material are bonded, and connected between the bumps and the first UBM layer; and
a second intermetallic compound structure, comprising an intermetallic compound in which at least a portion of the material of the bumps and the second metal material are bonded, and connected between the bumps and the second UBM layer to surround and seal at least a portion of the first UBM layer.

19. The semiconductor package of claim 18, wherein an area of a surface of the second UBM layer facing the first UBM layer, is greater than an area of a surface of the first UBM layer facing the second UBM layer.

20. The semiconductor package of claim 18, wherein a side surface of the first UBM layer comprises a shape that is more curved than a shape of a side surface of the second UBM layer.
